(19) United States
(12) Patent Application Publication
(10) Pub. No.: US 2008/0283874 A1
(43) Pub. Date: Nov. 20, 2008

(54) Field-Effect Transistors

(75) Inventors: Martinus P.J. Peeters, Weert (NL); Dagobert Michel de Leeuw, Eersel (NL); Femke Karina de Theije, Vught (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/570,918

(22) PCT Filed: Jun. 24, 2005
(86) PCT No.: PCT/IB2005/052101

§ 371 Date: Dec. 19, 2006

Related U.S. Application Data
(60) Provisional application No. 60/583,434, filed on Jun. 28, 2004.

(51) Int. Cl. H01L 21/208; H01L 29/772

(52) U.S. Cl. 257/213; 438/483; 257/E21.114; 257/E29.242

(57) ABSTRACT

The present invention provides a field-effect transistor and method for the fabrication of a field-effect transistor by deposition on a substrate (480), which method comprises a wet chemical deposition of materials that react to form a semi-conducting material. The materials deposited include cadmium, zinc, lead, tin, bismuth, antimony, indium, copper or mercury. The wet chemical deposition may be by chemical bath deposition or spray pyrolysis. A vacuum deposition process is not required.

### FIELD-EFFECT TRANSISTORS

The present invention relates to field-effect transistors and to methods for their production.

Field-effect transistors, in particular, thin film field-effect transistors (TFTs), have a wide variety of uses and potential uses in areas such as display or storage technology.

Several methods for the production of thin-film transistors have been reported in the art, see, for example, GB-A-2044994.

The epitaxial growth of cadmium sulfide on indium phosphide monocrystals using chemical deposition from cadmium ammonia-thiourea aqueous solution is reported in “Epitaxial growth of cadmium sulphide layers on indium phosphide from aqueous ammonia solutions”, D Lincot, R Ortega-Borges and M Froment, Appl. Phys. Lett., 64(5), 1995, 569. Materials produced by this method can be used for optoelectronic applications.

U.S. Pat. No. 4,360,542 describes a method for the manufacture of photovoltaic cells in which cadmium sulfide is deposited in thin films on a suitable substrate by way of thermal decomposition of a cadmium ammonia thiocyanate complex aqueous ammonia solution.

The fabrication of thin-film transistors containing a thin semiconducting film of CdS or CdSe using low temperature chemical bath decomposition methods has been reported, see, for example, “Preparation of thin-film transistors with chemical bath decomposited CdSe and CdS thin films”, F Y Gan and I Shih, IEEE Trans. Electron Devices, 49 (2002), 15.

The use of a chemical bath deposition technique for the deposition of thin films of CdS, CdSe, ZnS, ZnSe, PbS, SnS, Bi₂S₃, Bi₂Se₃, Sb₂S₃, CuS and CuSe is described in “Semiconductor thin films by chemical bath decomposition for solar energy related application”, P K Nair et al, Solar Energy Materials and Solar Cells, 52 (1998), 313-344. In the method described in that document, thin semiconductor films are deposited on substrates immersed in dilute solutions containing metal ions and a source of hydroxide, sulfide or selenide ions. It is reported that the chemical bath deposition technique is well suited for producing large-area thin films for solar energy related applications.

Chemical bath deposition of indium sulfide is also described in “Chemical bath deposition of indium sulphide thin films: preparation and characterization,” C. D. Lokhande, A. Ennaoui, P. S. Patil et al. Thin Solid Films 40 (1999) 18.

U.S. Pat. No. 5,689,125 describes semiconductor devices comprising an interface layer of cadmium sulfide (CdS). The interface layer is produced by the use of chemical bath deposition using a solution of ammonium hydroxide, hydrated cadmium sulphate (3CdSO₄8H₂O) and thiourea at 30 to 90° C.

These prior art methods using chemical bath deposition typically need to be followed by techniques such as lithography and etching to remove the deposited material from area of the substrate where it is not required. It would be advantageous to provide a method for depositing semi-conducting materials such as CdS that avoids the need for the use of these subtractive steps. The present applicants have developed such a method.

Deposition of indium sulfide, In₂S₃, by chemical spray pyrolysis to produce conductive films for optoelectronic and photovoltaic applications is described in “Characterisation of spray pyrolysed indium sulphide thin films”, T. T. John, S. Bini, Y. Kashiwaba et al., Semicond Sci. Technol. 18 (2003) 491.

Indium tracks can be transformed to In₂S₃ by thermal treatment in a flowing stream of H₂S, J. Herrero and J. Ortega Sol. Energy Mater 17 (1988) 357.

In polymer electronics based displays, the precursor pentacene is presently used as a semiconductor. The mobility of about 0.02 cm²/Vs limits the size of the displays to about QVGA (typically, 320 by 240 pixels). Higher mobility semiconductors are needed to increase either the refresh rate and/or to increase the size to VGA (720 by 400 pixels) and SVGA (800 by 600 pixels) sizes.

In commercially available active matrix liquid crystal displays amorphous hydrogenated silicon is used as the semiconductor. Processing is by standard semiconductor technologies, e.g. vacuum deposition followed by lithography and etching. The prior art methods of deposition of an active, high mobility semiconductor material require use of a vacuum technique. For reasons of cost and efficiency, a fabrication process that does not require vacuum deposition is desirable.

The listing or discussion of a prior-published document in this specification should not necessarily be taken as an acknowledgement that the document is part of the state of the art or is common general knowledge.

The present invention provides a method for the fabrication of semi-conductors, in particular, field-effect transistors in which semi-conducting material is deposited on a substrate by wet chemical deposition or by spray pyrolysis.

The method of the present invention is particularly suitable for the deposition of cadmium sulfide or indium sulfide onto a substrate.

In one embodiment this method comprises:

(i) providing a solution comprising a material that has semi-conducting properties or a combination of compounds that react to form a material having semi-conducting properties;

(ii) depositing droplets of the solution onto a substrate;

(iii) heating the product of step (ii) at a temperature of 50 to 90° C.;

(iv) rinsing the product of step (iii); and

(v) heating the product of step (iv) at a temperature of from 50 to 200° C.

The term “material having semi-conducting properties” as used herein, includes a substance whose electrical conductivity is intermediate between a metal and an insulator; its conductivity changes with changes in temperature, in the presence of impurities, when it is exposed to light, and/or in the presence of an electric field. Conductors generally have a resistivity below 10-5 Ωm, at about 25° C. and atmospheric pressure. Semi-conductors generally have resistivities in the range 10-5 Ωm to 108 Ωm, at about 25° C. and atmospheric pressure. Insulators generally have a resistivity above 108 Ωm, preferably at 25° C. and atmospheric pressure.

The material having semi-conducting properties may be any material having semi-conducting properties that is suitable for use in field-effect transistors. The method of the present invention is particularly suitable for the deposition of semi-conducting materials that can be deposited using chemical bath deposition techniques. Chemical bath deposition techniques are described in, for example, U.S. Pat. No. 5,689,125, Lincott et al., Appl. Phys Lett. 64(5), 31 Jan. 1994, Nair et al., Solar Energy Materials avid Solar Cells, 52 (1998), 313-344 and Gan and Shih, Transactions on Electronic Devices, Vol. 49, No. 1, January 2002.

The material having semi-conducting properties used in the present invention preferably comprises at least one of cadmium, zinc, lead, tin, bismuth, antimony, indium, copper and mercury. Preferably, the material having semi-conducting properties comprises cadmium or indium.

The material having semi-conducting properties used in the present invention preferably comprises at least one of sulfur, selenium and tellurium. Preferably, the material having semi-conducting properties comprises sulfur.

The person of ordinary skill in the art would appreciate what other materials having semi-conducting properties could be used in the method of the present invention.

Preferably a combination of compounds that react to form a material having semi-conducting properties is used in step (i). Combinations suitable for use in the present invention include those comprising a complex comprising at least one of cadmium, zinc, lead, tin, bismuth, antimony, indium, copper and mercury. Preferably a cadmium or indium containing complex is used.

If a complex is used in step (i), it may be obtained prior to step (i), by the reaction of a suitable starting material containing cadmium, zinc, lead, tin, bismuth, antimony, indium, copper or mercury with a material suitable for the formation of the complex. Preferably, a halogen salt, such as the chloride salt, of cadmium, zinc, lead, tin, bismuth, antimony, indium, copper or mercury or the acetate of cadmium, zinc, lead, tin, bismuth, antimony, indium, copper or mercury may be used.

Other starting materials that may be used to prepare the cadmium containing complex include cadmium halides such as cadmium chloride, CdCl₂ and dialkyls such as Cd(1-6 carbon alkyl)₂. As the skilled person will appreciate, the corresponding zinc, lead, tin, bismuth, antimony, indium, copper and mercury containing materials may be used to obtain complexes of these materials. The use of the chloride salt is particularly preferred.

The person of ordinary skill in the art would be able to readily determine what materials are suitable for forming complexes with the starting materials described above. Any suitable material may be used. Suitable materials include but are not limited, to ammonia, triethanolamine, citric acid and ethylenediamine. Preferably an ammonia containing solution is used. The use of ammonia is particularly preferred because it is easy to remove later in the reaction process if necessary. In a preferred aspect, the complex is obtained by mixing a solution of a chloride such as cadmium or indium chloride with an ammonia solution.

A suitable concentration for the ammonia solution is 1 to 5M, for example about 2M. A suitable concentration for cadmium chloride solution is 10×10⁻³ to 20×10⁻³ M, for example about 16×10⁻³ M. The skilled person will appreciate that alternatively, similar concentrations of other complex forming materials may be used.

Preferably, the complex forming materials are chosen such that the solution used in step (i) comprises a very low free cadmium, zinc, lead, tin, bismuth, antimony, indium, copper or mercury concentration. This is thought to reduce homogeneous precipitation onto the substrate and allow heterogeneous deposition of a precipitate onto the substrate.

Preferably the complex is an amine complex. The use of the tetraamine cadmium complex, Cd(NH₃)₄²⁺ is particularly preferred. The tetraamine cadmium complex, Cd(NH₃)₄²⁺ may be obtained using any method known in the art. For example, by the reaction of cadmium acetate with an ammonia solution. Preferably, the tetraamine cadmium complex, Cd(NH₃)₄²⁺ is obtained by mixing a solution of a cadmium halide such as cadmium chloride with an ammonia solution.

The present inventors have surprisingly found that, in certain circumstances, there are significant advantages associated with the use of halide salts such as chloride salts as opposed to acetates in the formation of the complexes used in step (i). It has been found that, when materials made using complexes derived from cadmium acetate are exposed to ambient light, a persistent photocurrent and a potentially unacceptable reduction in current modulation can occur in some circumstance. This effect is typically not seen when cadmium chloride is used as a starting material. Without wishing to be bound by theory, the present inventors believe that when cadmium chloride is used small amounts of chlorine are incorporated substitutionally into the CdS lattice. It is thought that this has the effect of pinning the Fermi level just below the conduction band, thus preventing the development of a persistent photocurrent.

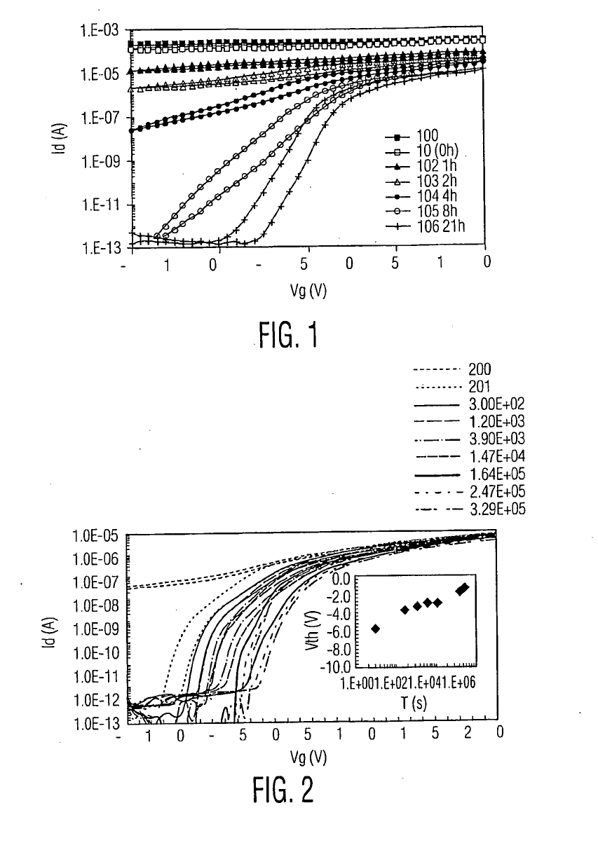

A comparison of FIGS. 1 and 2 shows the effect of using cadmium chloride rather than cadmium acetate. As illustrated in FIG. 1, the exposure of a material produced using cadmium acetate to ambient light led to a persistent photocurrent that persisted at room temperature for weeks and deteriorated the current modulation. FIG. 2 shows that when a material produced using cadmium chloride was subjected to ambient light and then put in the dark, the photocurrent almost immediately disappeared.

The combination used in step (i) preferably comprises a source of at least one of sulfur, selenium and tellurium ions. Any suitable source of sulfur ions may be used. Suitable sources of the sulfur ions include, but are not limited to, thiourea or thioacetamide. The concentration of the source of sulfur ions, for example thiourea, is preferably from 25×10⁻³ to 40×10⁻³ M, for example about 32×10⁻³ M. Any suitable source of selenium ions may be used. Suitable sources of selenium ions include, but are not limited to, sodium selenosulphate. Any suitable source of tellurium ions may be used. The skilled person will appreciate that the concentration of suitable sources of selenium ions or tellurium ions may be similar to those suggested above for the sulfur ions.

Ideally, the sources of sulfur, selenium and tellurium ions used should provide a slow release of the sulfur, selenium and tellurium ions leading to low concentrations of materials such as free HS⁻ and S₂⁻ and the prevention of the homogeneous precipitation of the material having semi-conducting properties.

Optionally, the material having semi-conducting properties may be doped. Suitable dopants are well known in the art.

The deposition step, step (ii) may take place at any suitable temperature. The most appropriate temperature will depend on factors such as the nature of the material to be deposited and the nature of the substrate. The person of ordinary skill in the art would be readily able to determine a suitable temperature. The method of the present invention is particularly suitable for use with compositions for which the optimum chemical bath deposition temperature is about 60 to 70° C. Thus, the solution to be deposited can be heated to such a temperature prior to deposition. Alternatively, the solution may be at a relatively low temperature, for example 0 to 35° C., for example at ambient temperature (about 15 to 30° C.), for example 20 to 25° C. and the substrate may be at a higher temperature, for example above 50° C., such as 60 to 70° C. When a heated substrate is used, the temperature of the material deposited on the substrate will rapidly increase to a temperature similar to that of the substrate due to the small size of the droplets deposited.

Any suitable method for depositing droplets of the solution onto the substrate may be used in step (ii). Suitable methods include, but are not limited to, inkjet printing, dispensing and the use of an aerosol in combination with an electrical field.

Any suitable substrate known for use in the manufacture of field-effect transistors may be used. The nature of the substrate will depend, at least to some extent on the desired final structure of the field effect transistor. The substrate may be an insulator or it may have conducting properties.

In one aspect of the invention, a substrate that may also act as a gate electrode may be used. Suitable substrates for use in this aspect include doped silicon wafers. Such wafers typically comprises a layer of thermally grown SiO₂ on their upper surface. The SiO2 layer is typically about 200 nm thick and has a capacitance of about 17 nF/cm².

The test substrates may contain any suitable source and drain electrodes, for example Au/Ti source and drain electrodes. These source and drain electrodes may be made by methods well known in the art. Suitable methods include standard photolithography on deposited metal films (see, for example, Field-effect transistors made from solution-processed organic semiconductors, A. R. Brown et al, Synthetic Metals, 88 (1997) 37-55).

Alternatively, polymeric test substrates may be used. If a polymer substrate is used, it may be flexible. Such substrates are described in “Flexible active-matrix displays and shift registers based on solution-processed organic semiconductors,” G. H. Gelinck et al, Nature Materials, 2004, 3(2), pages 106 to 110. Such substrates may comprise a support with a foil on top, then a planarisation layer, structured gold as gate electrode, a polymer such as the commercially available epoxy based negative resist SU8 as the gate dielectric, typically SU8 and gold source and drain electrodes. The materials disclosed as gate dielectrics in U.S. Pat. No. 6,635,406, which is incorporated by reference herein, may be used in embodiments of the present invention. These materials include not only commercially available polyepoxy-based photoresists such as SU8, but also hard-baked novolacs, conventional photoresists comprising polymers such as polyvinylphenols (e.g. UV flood-exposed PVPs), polyglutarimides, polyimides, polyvinylalcohols, polyisoprenes, polyepoxy-based resins, polyacrylates, polyvinylpyrrolidone, p-hydroxystyrene polymers, and melamino polymers. Commercially available novolac photoresists of the type that can be suitably used in the practice of the present invention include HPR 504. The gate dielectric may comprise an organic electrically insulating polymeric compound which is capable of being crosslinked, usually with a crosslinking agent. There are no restrictions on the selection of polymeric insulators. It has been found that polyvinylphenol and polyvinylalcohol are suitable insulating polymeric materials, of which polyvinylphenol is preferred. Suitable crosslinking agents include aminoplasts, such as hexamethoxymethylmelamine (HMMM).

Silicon dioxide (SiO₂) may be used as a gate dielectric. When SiO₂ is used as a gate dielectric it may be primed. An example of a primed substrate suitable for use in the present invention is a substrate comprising silicon dioxide gate dielectric and primed with hexamethyldisilazane. Such a primed substrate may be obtained by the gas phase reaction of bexamethyldisilazane with the surface of the substrate, for example to provide a monolayer of hexamethyldisilazane on the surface of the substrate. If necessary, the primer can be removed using fuming nitric acid or by plasma or UV/ozone treatment.

The size of the droplets deposited in step (ii) will depend on factors such as the deposition method used, the wettability of the surface of the substrate and the spreading or the droplets on the substrate (this will depend on factors such as the surface tension of the solution).

In step (iii), the product of step (ii) is typically heated at a temperature of 50 to 90° C., preferably 60 to 85° C., more preferably 65 to 80° C. and most preferably 70 to 75° C., for example about 70 or about 75° C. Step (iii) is typically conducted for a time period of less than 1 hour, preferably less that 30 minutes, more preferably less than 10 minutes, for example about 5 minutes. The time that step (iii) is carried out for will depend on factors such as the concentration, composition and temperature of the deposited solution.

Any suitable method of heating can be used in step (iii). For example, the substrate may be placed on a hot plate. Preferably the substrate is covered during step (iii) to prevent evaporation. It is preferable to cover the substrate during heating because evaporation changes the composition of the droplets, for example the pH may decrease and this affects the properties of the semiconductor layer.

Without wishing to be bound by theory, the heating step (iii) results in the formation of the material having semi-conducting properties on the surface of the substrate.

In step (iv), the product of step (iii) is rinsed. Preferably demineralized water is used in this step. The product of step (iii) may be rinsed for any suitable period of time, for example from 1 to 10 minutes, such as about 5 minutes.

As used herein, the term demineralized water refers to water from which minerals and/or salts have been removed.

Step (v) is typically conducted at a temperature of from 50 to 200° C., preferably 120 to 180° C., more preferably 140 to 160° C., for example about 150° C. Step (v) is typically carried out for a time period of 1 to 3 hours, preferably about 2 hours. Step (v) may be carried out under any suitable atmosphere, for example in an atmosphere of air or under vacuum. Preferably step (v) is carried out under vacuum. If step (v) is not carried out under vacuum any suitable pressure may be used, for example, a pressure a pressure of from 1×10⁻⁴ Mbar to atmospheric pressure.

The present invention also provides a field-effect transistor obtainable by a method described above. Optionally, the transistor of the present invention may comprise a source and/or drain electrode comprising a noble metal. Suitable noble metals include, but are not limited to, gold, silver, platinum and palladium. It is advantageous to use electrodes comprising one or more of these metals as they do not readily oxidize. Preferably the noble metal is gold. Alternatively, other high work function electrodes such as those comprising ITO or conductive polymers such as PEDOT (poly (3,4-ethylene dioxythiophene)) or PANI (polyaniline) may be used. PEDOT may also, for example, be used in the form of PEDOT/PSS (poly (3,4-ethylene dioxythiophene) stabilized with polystyrenesulfonic acid). PANI may be used in the form of PAM-CSA (polyaniline doped with camphorsulphonic acid).

Compared with the methods known in the art that include subtractive steps such as lithography and etching, the methods of the present invention have significant advantages in that the number of process steps is reduced and the amount of waste produced is reduced.

CdS is widely used as a high mobility semiconductor in research, however the major drawback of using CdS on a commercial scale is the toxicity of cadmium. By replacing cadmium with, for example, indium, this disadvantage can be prevented.

In another embodiment this method comprises:

(i) providing a solution comprising a material that has semi-conducting properties or a combination of compounds that react to form a material having semi-conducting properties;

(ii) heating a substrate to 220 to 450° C.; and

(iii) depositing droplets of the solution by spray pyrolysis onto the substrate at a temperature during deposition of 220 to 370° C.

The substrate may be highly doped silicon wafer or undoped silica or glass or polymeric material which is not deformed or degraded at the deposition temperature or any other material compatible with the deposition temperature and suitable for use in a metal oxide semiconductor.

The substrate may be annealed in a vacuum at about 150° C. to improve the contact between the source/drain and the semi-conducting film.

A combination of compounds suitable for spray pyrolysis and capable of reaction to form a material having semi-conducting properties may, for example, be a halide salt, in particular a chloride salt, of indium or cadmium, a source of sulfur ions and a source of oxygen.

Indium sulfide, In₂S₃, can be deposited by chemical spray pyrolysis. In one experiment a 1.5 ml of a spray solution containing 0.1 M InCl₃ and 0.15 M CS(NH₂)₂ was sprayed on a substrate at rate of about 1 ml/min. The substrate temperature was 300° C. FIG. 6 shows the linear and saturated transfer characteristics of this device measured at a drain bias of 2 and 20 V respectively. The mobility shown in FIG. 6 is high, in the order of 4 cm²/Vs. More optimal mobility is shown in the Table below. It is expected that mobility can be further optimized.

In the Figures:

FIG. 1: Shows the linear transfer characteristics of a CdS field-effect transistor after exposure to ambient light. Curve 100 is the transfer characteristic in ambient light. Curves 101-106 are transfer characteristics for various time periods in darkness. The transistor was produced using cadmium acetate in the chemical bath deposition process as described in the prior art. The photocurrent persisted, at room temperature, for a number of weeks.

FIG. 2: Shows the linear transfer characteristics of a CdS field-effect transistor after exposure to ambient light. The transistor was produced using cadmium chloride in the chemical bath deposition process as described in the prior art. Curve 200 is the transfer characteristic in ambient light. Curve 201 is the transfer characteristic in darkness. The curves for various time periods in darkness are indicated. Upon putting the transistor in the dark, the photocurrent almost immediately disappeared. The insert shows the threshold voltage as a function of time (T).

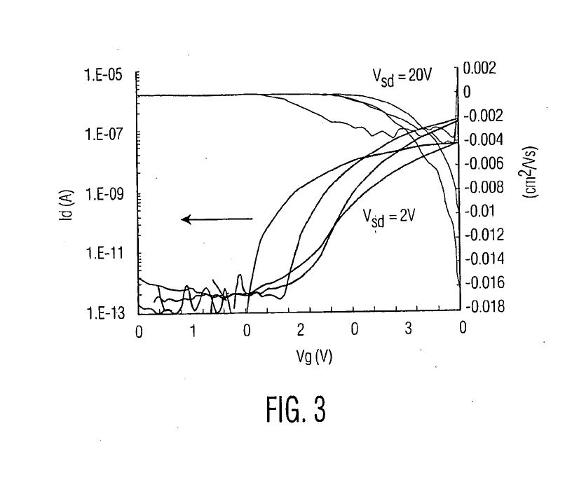

FIG. 3: Shows the linear and saturated transfer characteristics of a locally deposited CdS field-effect transistor obtained by the method described in Example 1 and having a channel length of 40 μm and a channel width of 1000 μm using gold source and drain contacts. The right y-axis is mobility (cm²/Vₛ).

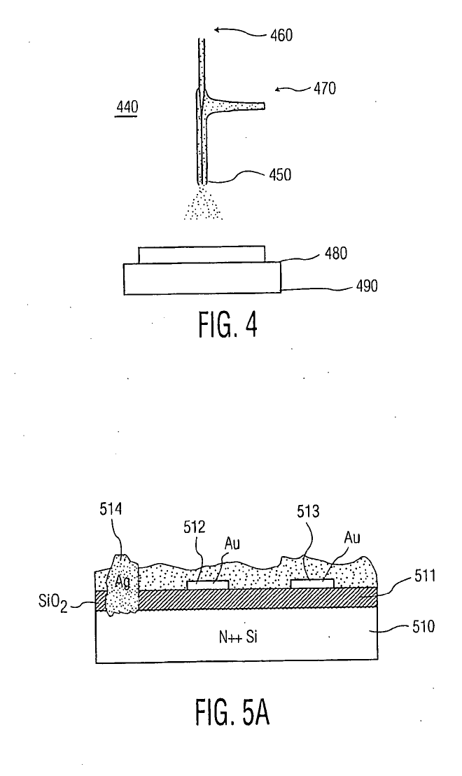

FIG. 4: Shows a nebulizer for spray pyrolysis.

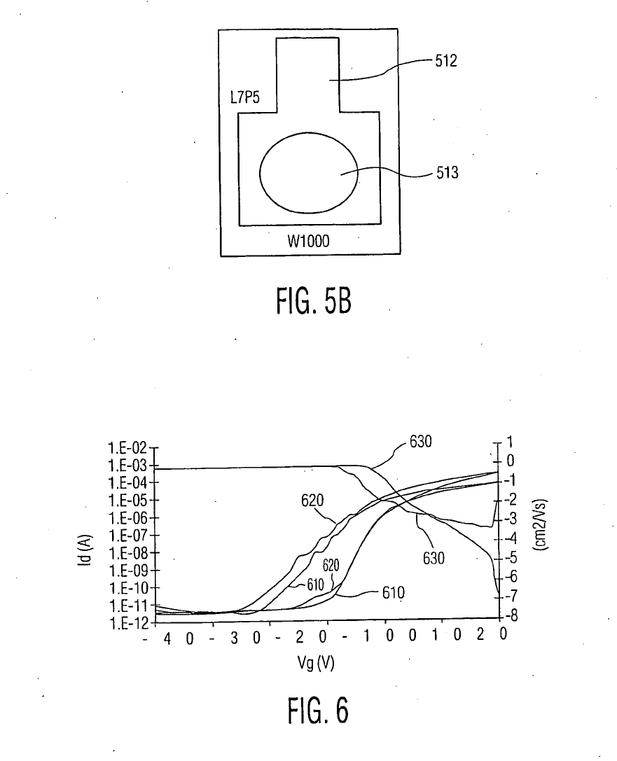

FIG. 5a: Shows a cross section of a field effect transistor test substrate.

FIG. 5b: Shows a top view of the field effect ring transistor test substrate.

FIG. 6: Shows linear and saturated transfer characteristics and derived mobility values for of an In₂S₃ field-effect transistor

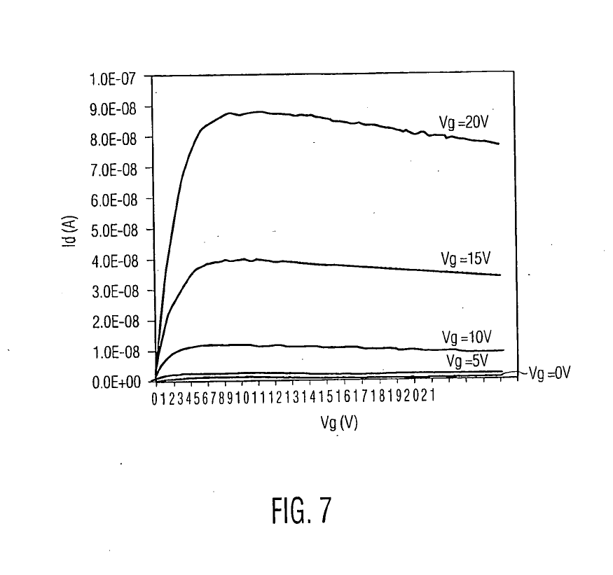

FIG. 7: Shows output characteristics of an In₂S₃ field-effect transistor.

The invention is illustrated by the following non-limiting examples.

### EXAMPLE 1

### Preparation of a Transistor by Selective Deposition of CdS onto a Substrate

A test substrate of a highly doped silicon wafer with thermally grown silicon oxide on top (about 100 nm) was used. Gold electrodes (with a titanium adhesion layer) are formed on the oxide layer using a combination of evaporation and lithography.

1 ml of a 2.5 M solution of CdCl₂ in water was added to a 2 M ammonia solution. After initial precipitation, a clear solution containing Cd(NH₃)₄²⁺ was obtained. To this solution, 3 ml of a 1.75 M solution of thiourea in water was added. The substrate was heated to 70° C. Droplets of the resulting solution were deposited on the test substrate using a syringe.

The substrate was placed on a hotplate at 75° C. and covered with a Petri-dish to prevent evaporation. After 5 minutes, the substrate was rinsed with demineralized water and then heated to 150° C. for 2 hours under vacuum.

The silicon wafer was used as the gate electrode, the two gold electrodes were the source and drain electrodes (contacted using micromanipulators). The transistor was characterised using an Agilent 4155c semiconductor parameter analyzer. Source drain voltage varied between 0 and 30 volts, source-drain voltage of 2 and 20 volts.

The transfer characteristics of the transistor obtained were measured. These are illustrated in FIG. 3.

### EXAMPLE 2

### Preparation of a Transistor by Deposition of In₂S₃ onto a Substrate

Experiments were initiated to use spray pyrolysis for the deposition of indium sulfide. Spray pyrolysis is based on evaporation of precursors at the vicinity of a substrate heated by a hotplate. Aerosol has been widely used as material source for the deposition of thin films.

The deposition of thin indium sulfide films was performed with a nebulizer 440 as in FIG. 4. The carrier gas flow 470 is introduced in the nebulizer main tube and leaves the nebulizer through the nozzle 450. Liquid 460 flows through to the nozzle 450 where it joins the carrier gas flow 470 and forms an aerosol. The aerosol is deposited on a substrate 480. The substrate 480 is heated by a hotplate 490. At optimum flow rate, the solvent evaporates close to the heated substrate surface. Here, the solvent is water. The solvent may also be an alcohol, mixture of water and alcohol (for example, methanol and water in equal parts), or may be another solvent, in particular an organic solvent. The solvent is typically a source of oxygen for the pyrolysis process. The carrier gas here is argon, but may be another inert gas or gas which is substantially inert under these process conditions, such as nitrogen.

The precursor is volatilized in the vicinity of the substrate and adsorbed onto the heated substrate surface. This is followed by decomposition and/or chemical reactions to yield a dense indium sulfide film. To obtain a larger deposition area, the nebulizer rotates above the surface.

The spray solution comprises a mixture of thiourea (CS(NH₂)₂) and indium chloride (InCl₃) solution in water. The pH of this solution is about 4. For some experiments this pH is lowered to 0 or 2 by adding HCl or acetic acid. The In/S ratio is varied by varying the molar concentrations of the precursors. In most experiments, the total volume and rate of the sprayed solution is 1 ml and 1 ml/min, argon is used as the carrier gas. The hotplate temperature is varied between 300 and 450° C. Due to cooling by the gas and liquid flow, the substrate temperature is about 80° C. lower. The spraying distance is kept at 6 cm, and the diameter of the rotation circle is about 3 cm. The indium to sulfur ratio was varied between 0.3 and 2. Particularly favorable electrical results are obtained for ratio's between of 0.9 and 1.04. For ratios of 1.2 and higher, conductive films are created. In Table 1, some particularly favorable and some typical results are summarized.

TABLE 1

| In/S | | In/S | | | amount | | | |
|---|---|---|---|---|---|---|---|---|
| ratio in | | concetration | flow rate | Deposition | sprayed | | mobility | off current |
| solution | PH | (M) | (ml/min) | T (° C.) | (ml) | Iₒₙ/I_{off} | (cm²/Vs) | (pA) |
| 1.04 | 4 | 0.1/0.104 | 0.73 | 270 | 1 ml | 10⁷ | 0.3 | 1 |
| 1.04 | 4 | 0.1/0.104 | 0.73 | 300 | 1 ml | 10⁵ | 0.1 | 1 |
| 1.04 | 4 | 0.1/0.104 | 0.73 | 330 | 1 ml | 10⁶ | 1 | 10 |
| 1.04 | 4 | 0.1/0.104 | 0.73 | 360 | 1 ml | 10⁴ | 6 | 10000 |
| 1 | 0 | 0.1/0/1 | 0.73 | 270 | 1.4 | 10⁵ | 0.6 | 50 |
| 1 | 0 | 0.1/0/1 | 0.73 | 300 | 1.4 | 10⁷ | 1 | 1 |
| 1 | 0 | 0.1/0/1 | 0.73 | 320 | 1.4 | 10⁶ | 4 | 10 |
| 1 | 4 | 0.1/0/1 | 0.73 | 274 | 1 | 10⁶ | 0.1 | 1 |
| 1 | 4 | 0.1/0/1 | 0.73 | 327 | 1 | 10⁶ | 0.5 | 1 |
| 1 | 4 | 0.1/0/1 | 0.73 | 359 | 1 | 10⁴ | 5 | 100 |

### Electrical Analysis

The nanocrystalline indium sulfide films are deposited on TFT (thin-film transistor) test substrates (FIGS. 5a and 5b), which consist of an N⁺⁺ silicon wafer 510 with 200 nm thermal SiO₂ 511 as gate dielectric (capacitance 1.7 10-8 F/cm²). On top, gold contacts are patterned by photolithography to form source 512 and drain 513. The gate oxide, here a silicon di-oxide 200 nm film, is primed with hexamethyl disilazane (HMDS), which yields a hydrophobic surface. The top contact 514 to the bottom gate here is silver. FIG. 5b is a top view of the field effect ring transistor test substrate, showing source 512 and drain 513 contacts.

The measurements are performed on ring transistors with a channel length of 40 μm and a width of 1000 μm. Drain sweeps (I_{drain} vs. V_{drain} at V_{gate} varying between −5 V and 20V in steps of 5 V) and gate sweeps (I_{drain} vs V_{gate} at V_{drain}=2 V and 20 V) are measured. A forward gate bias sweep as well as a backwards gate bias sweep is measured for both drain voltages. The mobility used in this report is measured in the gate bias sweep at V_{drain}=2V and at V_{gate}=20V. The current modulation is the ratio of the drain current at V_{gate}=−20V and V_{gate}=20V.

FIG. 6 shows linear 61 (V_{drain}=2 V) and saturated 62 (V_{drain}=20 V) transfer characteristics of a In₂S₃ field-effect transistor with a channel length of 40 μm and channel width of 1000 μm using gold source and drain contacts. The derived mobility values are presented by curve 63. The left y-axis is drain current. The x-axis is gate voltage. The right y-axis is mobility (cm²/Vₛ). The In/S ratio was 1.00.

FIG. 7 is a graph of output characteristics of a In₂S₃ field-effect transistor with a channel length of 40 μm and channel width of 1000 μm using gold source and drain contacts. The y-axis is drain current. The x-axis is drain voltage. The drain bias was swept from 0 V to 20 V and back at gate biases between 0 V and 20 V in steps of 5V. The output curves show that gold is an injecting, and not a Schottky contact.

Table 2 summarizes results from X-ray fluorescence (XRF) testing of composition in indium and sulfide thin films from different In/S ratios in precursor solutions.

TABLE 2
In and S composition in In₂S₃ thin films deposited from
different In/S ratio precursor solutions

| | In and S amounts | | |
|---|---|---|---|
| | 10¹⁵atoms/cm² | | |
| Precursor Sample | In | S | In/S |
| In/S = 0.7 | 39 | 51 | 0.76 |
| In/S = 0.8 | 35 | 49 | 0.7 |
| In/S = 0.9 | 27 | 39 | 0.71 |
| In/S = 1 | 34 | 26 | 1.33 |
| In/S = 1.04 | 41 | 50 | 0.82 |

In addition, Rutherford backscattering spectrometry (RBS) techniques were used to measure the amount of the following species: In, S, Cl and O as shown in Table 3.

TABLE 3
Composition measured by RBS of thin films prepared with
different sprayed solutions

| Precursor | Species amounts 10¹⁵ atoms/cm² | | | | Measured In/S ratio |
|---|---|---|---|---|---|
| Sample | In | S | Cl | O | in thin films |
| In/S = 0.7 | 24.3 | 33 | 5.4 | 4 | 0.74 |
| In/S = 0.5 | 32.7 | 45 | 5.5 | 3 | 0.73 |
| In/S = 0.9 | 37.6 | 49 | 6.7 | 6 | 0.77 |
| In/S = 1 | 33.8 | 26 | 12.7 | 23 | 1.30 |
| In/S = 1.04 | 39.5 | 46 | 8.5 | 10 | 0.86 |

These results are very similar to the XRF analysis and confirm the presence of a large amount of oxygen in the thin film at the In/S ratio of 1. Moreover, a large amount of chloride is noted in all the thin films, especially at the ratio of 1. Surprisingly, favorable electrical properties (current modulation of 7 decades, and mobility of 4.5 cm²/Vₛ) were found at an In/S ratio of 1 in the precursor which correlated with a higher chlorine and oxygen content and In/S ratio and presence of a cubic form of In₂S₃ in the semi-conducting film.

The precursor may also be deposited by ink-jet printing. Droplets of the solution may be deposited and converted by heat to semi-conductor. Residual liquid can be removed by rinsing. Alternatively, nanoparticles of a metal may be deposited by inkjet printing and subsequent cured to form semi-conductors, by for example, as disclosed in J. Herrero and J. Ortega, Sol. Energy Mater 17 (1988) 357, thermal treatment in a flowing stream of H₂S.

Finally, the above-discussion is intended to be merely illustrative of the present invention and should not be construed as limiting the appended claims to any particular embodiment or group of embodiments. Thus, while the present invention has been described in particular detail with reference to specific exemplary embodiments thereof, it should also be appreciated that numerous modifications and changes may be made thereto without departing from the broader and intended spirit and scope of the invention as set forth in the claims that follow. The specification and drawings are accordingly to be regarded in an illustrative manner and are not intended to limit the scope of the appended claims.

In interpreting the appended claims, it should be understood that:

(i) the word “comprising” does not exclude the presence of other elements or acts than those listed in a given claim;

(ii) the word “a” or “an” preceding an element does not exclude the presence of a plurality of such elements;

(iii) any reference signs in the claims do not limit their scope; and

(iv) several “means” may be represented by the same item or implemented structure or function.

1. A method for the fabrication of a field-effect transistor, which method comprises:
(i) providing a solution comprising a material that has semi-conducting properties or a combination of compounds that react to form a material having semi-conducting properties;
(ii) depositing droplets of the solution onto a substrate;
(iii) heating the product of step (ii) at a temperature of 50 to 90° C.;
(iv) rinsing the product of step (iii); and
(v) heating the product of step (iv) at a temperature of from 50 to 200° C.

2. A method according to claim 1, wherein the material having semi-conducting properties comprises at least one of cadmium, zinc, lead, tin, bismuth, antimony, indium, copper and mercury.

3. A method according to claim 2, wherein the material having semi-conducting properties comprises cadmium.

4. A method according to claim 2, wherein the material having semi-conducting properties comprises indium.

5. A method according to claim 1, wherein the material having semi-conducting properties comprises at least one of sulfur, selenium and tellurium.

6. A method according to claim 5, wherein the material having semi-conducting properties comprises sulfur.

7. A method according to claim 1, wherein a combination of compounds that react to form a material having semi-conducting properties is used in step (i).

8. A method according to claim 7, wherein the combination comprises a complex comprising at least one of cadmium, zinc, lead, tin, bismuth, antimony, indium, copper and mercury.

9. A method according to claim 8, wherein the complex is an amine complex.

10. A method according to claim 8 or 9, in which the complex is the tetraamine cadmium complex, Cd(NH₃)₄²⁺ or the tetraamine cadmium complex, In(NH₃)₄²⁺.

11. A method according to any one of claims 8 to 10, wherein, prior to step (i), the complex is obtained by the reaction of the chloride salt or the acetate of cadmium, zinc, lead, tin, bismuth, antimony, indium, copper or mercury with a material suitable for the formation of the complex.

12. A method according to claim 11, wherein the material suitable for forming the complex is an ammonia solution.

13. A method according to claim 10, wherein, prior to step (i), the tetraamine cadmium complex, Cd(NH₃)₄²⁺ is obtained by mixing a solution of cadmium chloride with an ammonia solution.

14. A method according to any one of claims 7 to 13, wherein the combination comprises a source of at least one of sulfur, selenium and tellurium ions.

15. A method according to claim 14, wherein the source of sulfur ions is thiourea or thioacetamide.

16. A method according to claim 14, wherein the source of selenium ions is sodium selenosulphate.

17. A field-effect transistor obtainable by a method according to any one of the preceding claims.

18. A transistor according to claim 17 additionally comprising a source and/or drain electrode comprising a noble metal.

19. A transistor according to claim 18, wherein the noble metal is gold.

20. A method for the fabrication of a field-effect transistor comprising:
(i) providing a solution comprising a material that has semi-conducting properties or one or more compounds that react to form a material having semi-conducting properties;
(ii) heating a substrate to a temperature in the range 220 to 450° C.; and
(iii) depositing droplets of the solution by spray pyrolysis onto the heated substrate.

21. The method of claim 20, wherein the material that has semi-conducting properties comprises at least one of cadmium, zinc, lead, tin, bismuth, antimony, indium, copper and mercury.

22. The method of claim 20, wherein the material having semi-conducting properties comprises at least one of sulfur, selenium and tellurium.

23. The method of claim 20, wherein the material having semi-conducting properties comprises indium and sulfur.

24. The method of claim 23, wherein the material having semi-conducting properties comprises indium and sulfur in an atomic ratio of from 0.7 to 1.33.

25. The method of claim 24, wherein the material having semi-conducting properties comprises indium and sulfur in an atomic ratio of from 0.82 to 1.33.

26. The method of claim 20 wherein the one or more compounds that react to form a material having semi-conducting properties comprise at least one of cadmium, zinc, lead, tin bismuth, antimony, indium, copper or mercury.

27. The method of claim 26, wherein the one or more compounds that react to form a material having semi-conducting properties comprise at least one of sulfur, selenium and tellurium.

28. The method of claim 20, wherein the one or more compounds that react to form a material having semi-conducting properties, comprises indium and sulfur, the atomic ratio of indium to sulfur in the one or more compounds that react to form a material having semi-conducting properties, being in the range from 0.3 to 1.2.

29. The method of claim 28, wherein the atomic ratio of indium to sulfur in the one or more compounds that react to form a material having semi-conducting properties is in the range from 0.9 to 1.04.

30. The method of claim 28, wherein the one or more compounds that react to form a material having semi-conducting properties further comprises a source of oxygen and chlorine.

31. The method of claim 26, wherein, prior to step (i), the one or more compounds that react to form a material having semi-conducting properties comprise a complex obtained by the reaction of the chloride salt or the acetate of cadmium, zinc, lead, tin, bismuth, antimony, indium, copper or mercury with a source of at least one of sulfur, selenium or tellurium ions.

32. The method of claim 31, wherein the source of sulfur ions comprises thiourea or thioacetamide.

33. A thin film transistor comprising indium sulfide.

34. The thin film transistor of claim 33 comprising a polymer substrate.

35. The thin film transistor of claim 33, further comprising a semi-conducting film in which the atomic ratio of indium to sulfur is between 0.7 and 1.33.

36. The thin film transistor of claim 35 in which the atomic ratio of indium to sulfur in the semi-conducting film is between 0.82 and 1.30.

37. The thin film transistor of claim 33 comprising a semi-conducting film in which the ratio of indium to sulfur is between 0.7 and 1.33, the semi-conducting film further comprising oxygen and chlorine.

38. A method for the fabrication of a field-effect transistor comprising:
(i) providing a solution comprising a material that has semi-conducting properties or is a combination of compounds that react to form the material having semi-conducting properties, the material comprising indium; and
(ii) depositing droplets of the solution by ink jet printing on a substrate.

39. A method for the fabrication of a field-effect transistor comprising:
(i) providing a solution comprising an element capable of reacting to form a material having semi-conducting properties, and
(ii) depositing the element on a substrate by ink jet printing on the substrate.

40. The method of claim 39, wherein the element is indium.

41. The method of claim 39, wherein the element is in the form of nanoparticles.

42. The method of claim 39, wherein the element is cadmium, zinc, lead, tin, bismuth, antimony, indium, copper or mercury.
